(19) United States
(12) Patent Application Publication
(10) Pub. No.: US 2022/0029265 A1
(43) Pub. Date: Jan. 27, 2022

(54) TRANSMISSION LINE AND METHOD FOR MANUFACTURING TRANSMISSION LINE

(71) Applicant: Murata Manufacturing Co., Ltd., Nagaokakyo-shi (JP)

(72) Inventors: Nobuyuki TENNO, Nagaokakyo-shi (JP); Nobuo IKEMOTO, Nagaokakyo-shi (JP); Takahiro BABA, Nagaokakyo-shi (JP); Kenji MATSUDA, Nagaokakyo-shi (JP)

(21) Appl. No.: 17/495,852

(22) Filed: Oct. 7, 2021

Related U.S. Application Data
(63) Continuation of application No. PCT/JP2020/023252, filed on Jun. 12, 2020.

(30) Foreign Application Priority Data
Jul. 8, 2019 (JP) 2019-126581

(51) Int. Cl. H01P 3/08; H01P 11/00

(52) U.S. Cl. CPC H01P 3/08; H01P 11/003

(57) ABSTRACT

A transmission line includes a ground conductor between first and second signal conductors. A substrate includes a first insulating layer and a second insulating layer having a relative permittivity lower than a relative permittivity of the first insulating layer. The first and second insulating layers are laminated in the thickness direction of the substrate and in contact with each other. The first and second signal conductors and the ground conductor are on an interface at which the first and second insulating layers are in contact with each other. The first and second signal conductors and the ground conductor each include a surface in contact with the first insulating layer and a surface in contact with the second insulating layer, the surface in contact with the second insulating layer being larger than the surface in contact with the first insulating layer.

### CROSS REFERENCE TO RELATED APPLICATIONS

This application claims the benefit of priority to Japanese Patent Application No. 2019-126581 filed on Jul. 8, 2019 and is a Continuation Application of PCT Application No. PCT/JP2020/023252 filed on Jun. 12, 2020. The entire contents of each application are hereby incorporated herein by reference.

### BACKGROUND OF THE INVENTION

### 1. Field of the Invention

The present invention relates to a transmission line including multiple signal conductors extending parallel or substantially parallel to each other in an insulating substrate.

### 2. Description of the Related Art

Japanese Unexamined Patent Application Publication No. 2016-92561 discloses a transmission line including multiple signal conductors disposed in a laminated insulator. The transmission line disclosed in Japanese Unexamined Patent Application Publication No. 2016-92561 includes a first signal conductor and a second signal conductor inside the laminated insulator. The first signal conductor and the second signal conductor include a conductor pattern with a line shape and are disposed at a distance from each other in the width direction of the laminated insulator.

A cavity is formed between the first signal conductor and the second signal conductor in the laminated insulator.

Although the cavity disposed in the transmission line disclosed in Japanese Unexamined Patent Application Publication No. 2016-92561 suppresses coupling between the first signal conductor and the second signal conductor, the strength of the transmission line is likely to decrease, and the transmission line is likely to be damaged.

### SUMMARY OF THE INVENTION

Preferred embodiments of the present invention provide highly reliable transmission lines each including multiple signal conductors with coupling between each other being reduced or prevented.

A transmission line according to a preferred embodiment of the present invention includes an insulating substrate, a first signal conductor, a second signal conductor, a first ground conductor, a second ground conductor, and a third ground conductor. The first ground conductor and the second ground conductor are disposed at a distance from each other in a thickness direction of the substrate. The first signal conductor and the second signal conductor are side by side in a width direction of the substrate and between the first ground conductor and the second ground conductor in the thickness direction of the substrate without any other conductor pattern interposed between the first ground conductor and the second ground conductor, the first signal conductor and the second signal conductor each being combined with the first ground conductor and the second ground conductor and defining a strip line. The third ground conductor is between the first signal conductor and the second signal conductor in the width direction. The substrate includes a first insulating layer and a second insulating layer having a second relative permittivity lower than a first relative permittivity of the first insulating layer. The first insulating layer and the second insulating layer are laminated in the thickness direction of the substrate and are in contact with each other. The first signal conductor, the second signal conductor, and the third ground conductor are disposed on an interface at which the first insulating layer and the second insulating layer are in contact with each other. The first signal conductor, the second signal conductor, and the third ground conductor each include a surface in contact with the second insulating layer and a surface in contact with the first insulating layer, the surface in contact with the second insulating layer being larger than the surface in contact with the first insulating layer.

Since the third ground conductor is disposed between the first signal conductor and the second signal conductor in this configuration, the isolation between the first signal conductor and the second signal conductor is improved. Further, the region between the first signal conductor and the third ground conductor and the region between the second signal conductor and the third ground conductor are primarily occupied by the second insulating layer, which has a low relative permittivity. Consequently, unnecessary coupling between the first signal conductor and the third ground conductor and between the second signal conductor and the third ground conductor and unnecessary coupling between the first signal conductor and the second signal conductor via the insulating layers are reduced or prevented. In addition, since the substrate does not include a cavity, a decrease in strength is avoided.

According to preferred embodiments of the present invention, highly reliable transmission lines each including multiple signal conductors with coupling between each other being reduced or prevented are able to be provided.

The above and other elements, features, steps, characteristics and advantages of the present invention will become more apparent from the following detailed description of the preferred embodiments with reference to the attached drawings.

### BRIEF DESCRIPTION OF THE DRAWINGS

FIG. 1 is a cross-sectional view of a transmission line according to a first preferred embodiment of the present invention.

FIG. 2 is an exploded perspective view of the transmission line according to the first preferred embodiment of the present invention.

FIGS. 3A to 3C are exploded plan views of the transmission line according to the first preferred embodiment of the present invention.

FIG. 4 is a side sectional view of an electronic device according to a preferred embodiment of the present invention.

FIG. 5 is a cross-sectional view of a transmission line according to a second preferred embodiment of the present invention.

FIG. 6 is a cross-sectional view of a transmission line according to a third preferred embodiment of the present invention.

FIG. 7 is a cross-sectional view of a transmission line according to a fourth preferred embodiment of the present invention.

FIG. 8A is a longitudinal sectional view of a lead-wire structure of the transmission line according to the first preferred embodiment of the present invention, and FIG. 8B is a longitudinal sectional view of another aspect of a lead-wire structure of the transmission line according to the first preferred embodiment of the present invention.

### DETAILED DESCRIPTION OF THE PREFERRED EMBODIMENTS

Preferred embodiments of the present invention will be described in detailed with reference to the drawings.

### First Preferred Embodiment

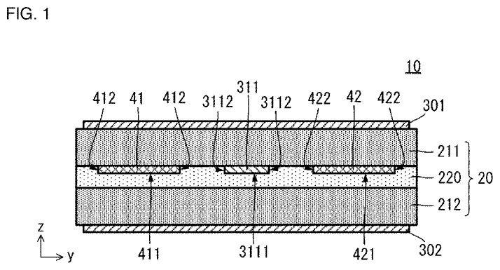

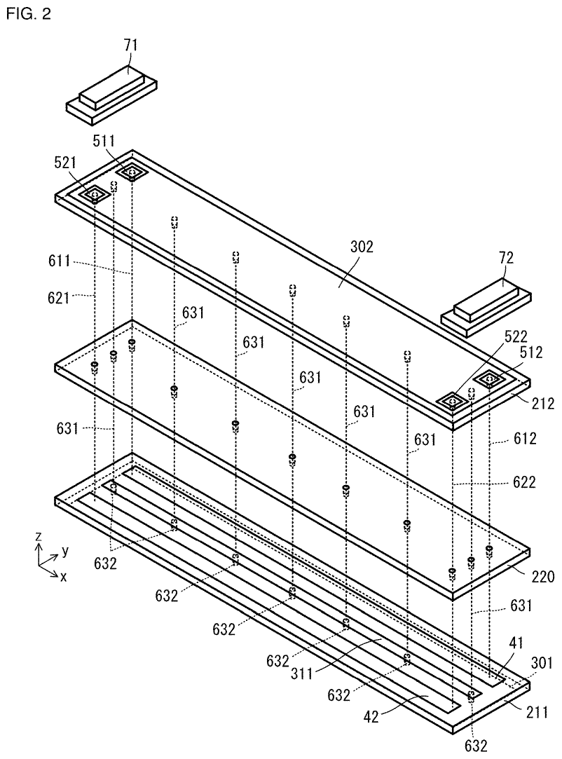

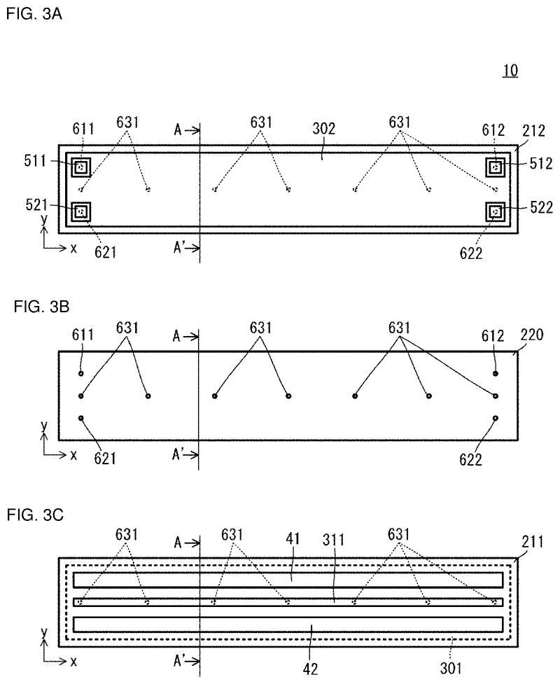

A transmission line according to a first preferred embodiment of the present invention will be described with reference to the drawings. FIG. 1 is a cross-sectional view of the transmission line according to the first preferred embodiment. FIG. 2 is an exploded perspective view of the transmission line according to the first preferred embodiment. FIGS. 3A to 3C are exploded plan views of the transmission line according to the first preferred embodiment. Relative dimensions in each figure are exaggerated as appropriate to facilitate understanding of the configuration.

As shown in FIG. 1, FIG. 2, FIGS. 3A to 3C, a transmission line 10 includes a substrate 20, a ground conductor 301, a ground conductor 302, a signal conductor 41, a signal conductor 42, and a ground conductor 311. The ground conductor 301 corresponds to a “first ground conductor”, the ground conductor 302 corresponds to a “second ground conductor”, and the ground conductor 311 corresponds to a “third ground conductor”. The signal conductor 41 corresponds to a “first signal conductor”, and the signal conductor 42 corresponds to a “second signal conductor”.

The substrate 20 is insulating. The substrate 20 has a plate shape and is elongated, for example, in one direction (the X direction in FIG. 2, FIGS. 3A to 3C). In the following description, it is assumed that the direction in which the substrate 20 is elongated (the longitudinal direction) is the X direction, the thickness direction of the substrate 20 is the Z direction, and a direction perpendicular or substantially perpendicular to the X direction and the Z direction of the substrate 20 is the Y direction.

The substrate 20 includes an insulating layer 211, an insulating layer 212, and an insulating layer 220. The insulating layer 211 corresponds to a “first insulating layer”, and the insulating layer 212 corresponds to a “third insulating layer”. The insulating layer 220 corresponds to a “second insulating layer”.

The insulating layers 211, 212, and 220 have the same or substantially the same shape in plan view (the shape viewed in the Z direction). A relative permittivity ε1 (a “first relative permittivity”) of the insulating layer 211 and a relative permittivity ε3 (a “third relative permittivity”) of the insulating layer 212 are higher than a relative permittivity ε2 (a “second relative permittivity”) of the insulating layer 220.

The insulating layer 220 has an adhesive function. The insulating layer 220 is disposed between the insulating layer 211 and the insulating layer 212 in the Z direction, and thus the insulating layer 211 and the insulating layer 212 are joined by the insulating layer 220.

The insulating layer 211 and the insulating layer 212 are mainly made of, for example, polyimide. Specifically, the insulating layer 211 and the insulating layer 212 are mainly made of, for example, liquid crystal polymer (LCP), which has good high-frequency characteristics. The insulating layer 220 is mainly made of, for example, fluoride-compound resin.

The ground conductor 301 is provided on a first main surface of the insulating layer 211. In other words, the ground conductor 301 is provided on the surface on the opposite side of the insulating layer 211 from the surface (a second main surface) in contact with the insulating layer 220. The ground conductor 301 entirely or substantially entirely covers the first main surface of the insulating layer 211.

The ground conductor 302 is provided on a first main surface of the insulating layer 212. In other words, the ground conductor 302 is provided on the surface on the opposite side of the insulating layer 212 from the surface (a second main surface) in contact with the insulating layer 220. The ground conductor 302 entirely or substantially entirely covers the first main surface of the insulating layer 212.

The signal conductor 41, the signal conductor 42, and the ground conductor 311 are provided on the second main surface of the insulating layer 211. In other words, the signal conductor 41, the signal conductor 42, and the ground conductor 311 are provided on the surface of the insulating layer 211, the surface being in contact with the insulating layer 220 (the surface being a junction interface).

The signal conductor 41, the signal conductor 42, and the ground conductor 311 face the ground conductor 301 and the ground conductor 302.

The signal conductor 41, the signal conductor 42, and the ground conductor 311 are each a conductor having a line shape extending in the X direction. The signal conductor 41, the signal conductor 42, and the ground conductor 311 extend parallel or substantially parallel to each other at a distance from each other in the width direction (the Y direction) of the substrate 20. The ground conductor 311 is disposed in the middle between the signal conductor 41 and the signal conductor 42 in the Y direction in this configuration.

The signal conductor 41 is combined with the ground conductor 301 and the ground conductor 302 and forms a strip line in this configuration. The signal conductor 42, the ground conductor 301 and the ground conductor 302 define a strip line. Specifically, the transmission line 10 includes a first strip line and a second strip line. The first strip line has a structure in which the signal conductor 41 is interposed between the ground conductor 301 and the ground conductor 302, and the second strip line has a structure in which the signal conductor 42 is interposed between the ground conductor 301 and the ground conductor 302. The first strip line and the second strip line are disposed at a distance from each other in the Y direction and extend parallel or substantially parallel to each other in the X direction.

At one end in the elongation direction, the signal conductor 41, which defines the first strip line, is connected to a terminal conductor 511 by an interlayer connecting conductor 611, the terminal conductor 511 being provided on the first main surface of the insulating layer 212. The terminal conductor 511 has a rectangular or substantially rectangular conductor pattern and is physically isolated from the ground conductor 302.

At the other end in the elongation direction, the signal conductor 41, which defines the first strip line, is connected to a terminal conductor 512 by an interlayer connecting conductor 612, the terminal conductor 512 being provided on the first main surface of the insulating layer 212. The terminal conductor 512 has a rectangular or substantially rectangular conductor pattern and is physically isolated from the ground conductor 302.

At one end in the elongation direction, the signal conductor 42, which defines the second strip line, is connected to a terminal conductor 521 by an interlayer connecting conductor 621, the terminal conductor 521 being provided on the first main surface of the insulating layer 212. The terminal conductor 521 has a rectangular or substantially rectangular conductor pattern and is physically isolated from the ground conductor 302.

At the other end in the elongation direction, the signal conductor 42, which defines the second strip line, is connected to a terminal conductor 522 by an interlayer connecting conductor 622, the terminal conductor 522 being provided on the first main surface of the insulating layer 212. The terminal conductor 522 has a rectangular or substantially rectangular conductor pattern and is physically isolated from the ground conductor 302.

A connector 71 is connected to the terminal conductor 511, the terminal conductor 521, and the ground conductor 302. In this way, an external-connection portion is provided at one end of the first and second strip lines of the transmission line 10. A connector 72 is connected to the terminal conductor 512, the terminal conductor 522, and the ground conductor 302. In this way, an external-connection portion is provided at the other end of the first and second strip lines of the transmission line 10. At least one of the connectors 71 and 72 may be removed.

In this configuration, the ground conductor 311 is disposed between the signal conductor 41 and the signal conductor 42. In this way, coupling between the signal conductor 41 and the signal conductor 42 is reduced or prevented. In other words, isolation between the first strip line and the second strip line that are provided in the substrate 20 can be improved.

The ground conductor 311 is connected to the ground conductor 301 by multiple interlayer connecting conductors 631. The multiple interlayer connecting conductors 631 are disposed at a predetermined distance from each other in the X direction. In this way, isolation between the first strip line and the second strip line is further improved.

The ground conductor 311 is connected to the ground conductor 302 by multiple interlayer connecting conductors 632. The multiple interlayer connecting conductors 632 are disposed at a predetermined distance from each other in the X direction. In this way, isolation between the first strip line and the second strip line is further improved.

The transmission line 10 further includes the following configuration.

As shown in FIG. 1, the entirety or substantially the entirety of a main surface 411 of the signal conductor 41 is in contact with the insulating layer 220. The main surface 411 is located on the opposite side of the signal conductor 41 from the surface in contact with the insulating layer 211. In addition, the entirety or substantially the entirety of side surfaces 412 that are connected to the main surface 411 is in contact with the insulating layer 220. Although FIG. 1 shows the entirety of the side surfaces 412 being in contact with the insulating layer 220, it is sufficient that the area of the side surfaces 412 in contact with the insulating layer 220 is larger than the area of the side surfaces 412 in contact with the insulating layer 211. In other words, it is sufficient that the signal conductor 41 is embedded in the insulating layer 220, for example, up to half of the height or more of the signal conductor 41.

Similarly, the entirety or substantially the entirety of a main surface 421 of the signal conductor 42 is in contact with the insulating layer 220. The main surface 421 is located on the opposite side of the signal conductor 42 from the surface in contact with the insulating layer 211. In addition, the entirety or substantially the entirety of side surfaces 422 that are connected to the main surface 421 is in contact with the insulating layer 220. Although FIG. 1 shows the entirety of the side surfaces 422 being in contact with the insulating layer 220, it is sufficient that the area of the side surfaces 422 in contact with the insulating layer 220 is larger than the area of the side surfaces 422 in contact with the insulating layer 211. In other words, it is sufficient that the signal conductor 42 is embedded in the insulating layer 220, for example, up to half of the height or more of the signal conductor 42.

Further, the entirety or substantially the entirety of a main surface 3111 of the ground conductor 311 is in contact with the insulating layer 220. The main surface 3111 is located on the opposite side of the ground conductor 311 from the surface in contact with the insulating layer 211. In addition, the entirety or substantially the entirety of side surfaces 3112 that are connected to the main surface 3111 is in contact with the insulating layer 220. Although FIG. 1 shows the entirety of the side surfaces 3112 being in contact with the insulating layer 220, it is sufficient that the area of the side surfaces 3112 in contact with the insulating layer 220 is larger than the area of the side surfaces 3112 in contact with the insulating layer 211. In other words, it is sufficient that the ground conductor 311 is embedded in the insulating layer 220, for example, up to half of the height or more of the ground conductor 311.

Such a configuration enables the region between the signal conductor 41 and the ground conductor 311 and the region between the signal conductor 42 and the ground conductor 311 to be predominantly occupied by the insulating layer 220 of a relative permittivity. In this way, unnecessary coupling between the signal conductor 41 and the ground conductor 311 and between the signal conductor 42 and the ground conductor 311 is reduced or prevented. Consequently, isolation between the first strip line and the second strip line is further improved.

In addition, this configuration can reduce the spacing between the signal conductor 41 and the ground conductor 311 and the spacing between the signal conductor 42 and the ground conductor 311. Thus, the transmission line 10 can be downsized.

Further, this configuration can partially reduce the relative permittivity of the region surrounding the signal conductor 41 and the signal conductor 42. Thus, transmission losses of the first and second strip lines can be reduced.

Further, the transmission line 10 in this configuration does not include a cavity inside the substrate 20. Thus, the transmission line 10 is unlikely to be damaged and has high reliability.

The transmission line 10 having such a configuration can be manufactured, for example, by the following non-limiting example method.

The ground conductor 301 is formed on the first main surface of the insulating layer 211 having the first relative permittivity, and the signal conductor 41, the signal conductor 42, and the ground conductor 311 are formed on the second main surface of the insulating layer 211.

The ground conductor 302 is formed on the first main surface of the insulating layer 212 having the third relative permittivity.

The insulating layer 211 and the insulating layer 212 are joined by the insulating layer 220, which has the second relative permittivity lower than the first relative permittivity and the third relative permittivity and has an adhering function, so that the second main surface of the insulating layer 211 and the second main surface of the insulating layer 212 face each other.

In this configuration, the signal conductor 41, the signal conductor 42, and the ground conductor 311 are embedded in the insulating layer 220 such that the signal conductor 41, the signal conductor 42, and the ground conductor 311 each include a surface in contact with the insulating layer 220 larger than a surface in contact with the insulating layer 211.

The transmission line 10 can be manufactured by using a non-limiting example manufacturing method as is described above. Since the insulating layer 211 and the insulating layer 212 are hardly deformed, a change in the electric characteristics due to misalignment can be reduced or prevented. Since the insulating layer 220, which can be deformed, has a low relative permittivity and does not include a conductor pattern, a variation in the amount of deformation of the insulating layer 220 does not significantly affect the electric characteristics.

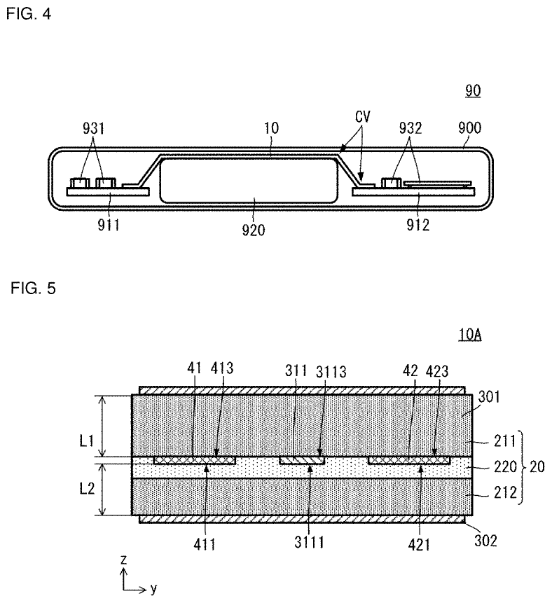

The transmission line 10 having such a configuration is used, for example, for an electronic device described below. FIG. 4 is a side sectional view of an electronic device according to a preferred embodiment of the present invention.

As shown in FIG. 4, an electronic device 90 includes the transmission line 10, a housing 900, a board 911, a board 912, a battery 920, electronic components 931, and electronic components 932. The transmission line 10, the board 911, the board 912, the battery 920, the electronic components 931, and the electronic components 932 are disposed inside the housing 900.

The battery 920 is disposed between the board 911 and the board 912. A component disposed between the board 911 and the board 912 is not limited to the battery 920. The electronic components 931 are mounted on the board 911, and the electronic components 932 are mounted on the board 912.

The transmission line 10 is connected to the board 911 at one end, for example, by the connector 71 described above. The transmission line 10 is connected to the board 912 at the other end, for example, by the connector 72 described above. The transmission line 10 is disposed along a portion of the outline of the battery 920 and includes bending portions CV in this configuration. As described above, the transmission line 10 does not include a cavity inside the substrate 20 and is unlikely to be damaged even though the transmission line 10 includes the bending portions CV. Thus, the electronic device 90 has high reliability.

### Second Preferred Embodiment

A transmission line according to a second preferred embodiment of the present invention will be described with reference to the drawing. FIG. 5 is a cross-sectional view of the transmission line according to the second preferred embodiment.

As shown in FIG. 5, a transmission line 10A according to the second preferred embodiment differs from the transmission line 10 according to the first preferred embodiment in that a distance L1 and a distance L2 are specified, the distance L1 being a distance at which the signal conductor 41 and the signal conductor 42 are disposed from the ground conductor 301 and the distance L2 being a distance at which the signal conductor 41 and the signal conductor 42 are disposed from the ground conductor 302. Other configurations of the transmission line 10A are the same as or similar to the configurations of the transmission line 10 and will not be described.

The distance L1 is set to be larger than the distance L2 (L1 >L2) for the transmission line 10A. Such a configuration can reduce or prevent the spread of an electric field from the signal conductor 41 and the signal conductor 42 toward the ground conductor 301.

Such a configuration of the transmission line 10A can reduce or prevent coupling between the first strip line, which includes the signal conductor 41, and the second strip line, which includes the signal conductor 42.

### Third Preferred Embodiment

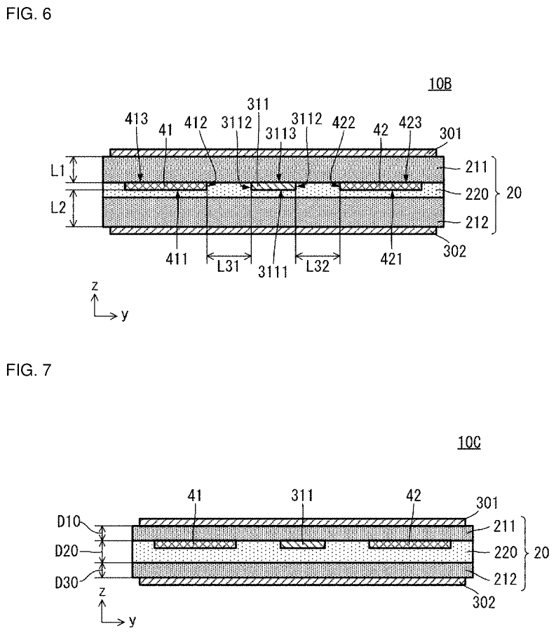

A transmission line according to a third preferred embodiment of the present invention will be described with reference to the drawing. FIG. 6 is a cross-sectional view of the transmission line according to the third preferred embodiment.

As shown in FIG. 6, a transmission line 10B according to the third preferred embodiment differs from the transmission line 10A according to the second preferred embodiment in that a spacing L31 between the signal conductor 41 and the ground conductor 311 and a spacing L32 between the signal conductor 42 and the ground conductor 311 are specified. Other configurations of the transmission line 10B are the same as or similar to the configurations of the transmission line 10A and will not be described.

The spacing L31 and the spacing L32 are larger than the distance L1 and the distance L2 in the transmission line 10B (L31 >L1, L32 >L1, L31 >L2, and L32 >L2). Such a configuration can reduce or prevent coupling between the signal conductor 41 and the signal conductor 42 via the ground conductor 311.

Such a configuration of the transmission line 10B can reduce or prevent coupling between the first strip line, which includes the signal conductor 41, and the second strip line, which includes the signal conductor 42.

Although the spacing L31 and the spacing L32 may differ from each other, the spacing L31 and the spacing L32 are preferably equal or substantially equal to each other if radio-frequency signals having the same or approximately the same frequencies are transmitted through the first strip line and the second strip line. In this case, L31=L32=L3 >L1 and L3 >L2.

### Fourth Preferred Embodiment

A transmission line according to a fourth preferred embodiment of the present invention will be described with reference to the drawing. FIG. 7 is a cross-sectional view of the transmission line according to the fourth preferred embodiment.

As shown in FIG. 7, a transmission line 10C according to the fourth preferred embodiment differs from the transmission line 10 according to the first preferred embodiment in that a thickness D10 (length in the Z direction) of the insulating layer 211, a thickness D20 (length in the Z direction) of the insulating layer 220, and a thickness D30 (length in the Z direction) of the insulating layer 212 are specified. Other configurations of the transmission line 10C are the same as or similar to the configurations of the transmission line 10 and will not be described.

The thickness D20 is larger than the thickness D10 and the thickness D30 in the transmission line 10C (D20 >D10 and D20 >D30). Such a configuration can reduce the thickness of the substrate 20 while reducing or preventing the change in the characteristic impedance.

### Lead-Wire Structure to Outside

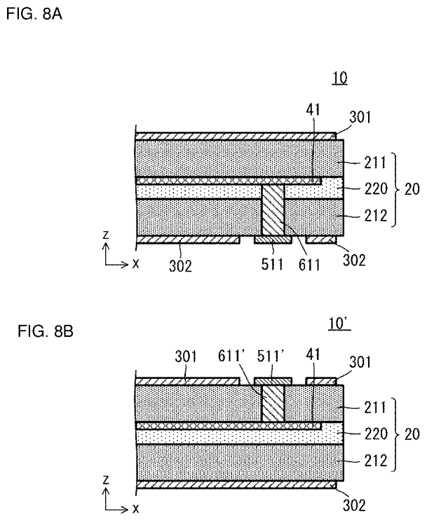

FIG. 8A is a longitudinal sectional view of a lead-wire structure of the transmission line according to the first preferred embodiment, and FIG. 8B is a longitudinal sectional view of another aspect of a lead-wire structure of the transmission line according to the first preferred embodiment. While a lead-wire structure at one end of the signal conductor 41 will be described as an example with reference to FIGS. 8A and 8B, the same or similar configuration can be used for other signal conductors and other end portions.

The interlayer connecting conductor 611 penetrates the insulating layer 220 and the insulating layer 212 in the thickness direction in the transmission line 10 as shown in FIG. 8A. The signal conductor 41 and the interlayer connecting conductor 611 are connected in this configuration, and a radio-frequency signal changes the transmission direction in the insulating layer 220, which has a lower relative permittivity. This configuration reduces a parasitic inductance component, and the transmission line 10 can achieve good transmission characteristics.

A terminal conductor 511′ is provided on the first main surface of the insulating layer 211, that is, on the main surface on which the ground conductor 301 is provided in the transmission line 10′ as shown in FIG. 8B. An interlayer connecting conductor 611′ penetrates the insulating layer 211 in the thickness direction. The interlayer connecting conductor 611′ in this configuration connects the signal conductor 41 and the terminal conductor 511′. Since the interlayer connecting conductor 611′ is provided in the insulating layer 211, which is hardly deformed, in this configuration, a through hole in which the interlayer connecting conductor 611′ is provided and that has a required shape can be easily manufactured with highly precise dimensions.

The configuration in each preferred embodiment described above may be combined as appropriate and an operation and advantageous effects may be obtained in accordance with each combination.

While preferred embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. A transmission line comprising:
an insulating substrate;
a first ground conductor and a second ground conductor spaced at a distance from each other in a thickness direction of the insulating substrate;
a first signal conductor and a second signal conductor side by side in a width direction of the substrate and between the first ground conductor and the second ground conductor in the thickness direction without any other conductor pattern interposed between the first ground conductor and the second ground conductor, the first signal conductor and the second signal conductor each being combined with the first ground conductor and the second ground conductor and defining a strip line; and
a third ground conductor between the first signal conductor and the second signal conductor in the width direction; wherein
the substrate includes:
a first insulating layer; and
a second insulating layer having a second relative permittivity lower than a first relative permittivity of the first insulating layer; and
the first insulating layer and the second insulating layer are laminated in the thickness direction of the substrate and are in contact with each other;
the first signal conductor, the second signal conductor, and the third ground conductor are on an interface at which the first insulating layer and the second insulating layer are in contact with each other;
the first signal conductor, the second signal conductor, and the third ground conductor each include a surface in contact with the second insulating layer and a surface in contact with the first insulating layer; and
the surface in contact with the second insulating layer is larger than the surface in contact with the first insulating layer.

2. The transmission line according to claim 1, wherein the third ground conductor extends parallel or substantially parallel to the first signal conductor and the second signal conductor and is connected to the first ground conductor by interlayer connecting conductors at a plurality of positions in an extending direction thereof.

3. The transmission line according to claim 1, wherein
the first ground conductor is opposite to the first signal conductor, the second signal conductor, and the third ground conductor such that the first insulating layer is interposed between the first ground conductor and the first signal conductor, the second signal conductor, and the third ground conductor;
the second ground conductor is opposite to the first signal conductor, the second signal conductor, and the third ground conductor such that the second insulating layer is interposed between the second ground conductor and the first signal conductor, the second signal conductor, and the third ground conductor;
the first signal conductor, the second signal conductor, and the third ground conductor are spaced at a distance L1 from the first ground conductor;
the first signal conductor, the second signal conductor, and the third ground conductor are spaced at a distance L2 from the second ground conductor; and
L1 >L2.

4. The transmission line according to claim 1, wherein
the first ground conductor is opposite to the first signal conductor, the second signal conductor, and the third ground conductor such that the first insulating layer is interposed between the first ground conductor and the first signal conductor, the second signal conductor, and the third ground conductor;
the second ground conductor is opposite to the first signal conductor, the second signal conductor, and the third ground conductor such that the second insulating layer is interposed between the second ground conductor and the first signal conductor, the second signal conductor, and the third ground conductor;
the first signal conductor, the second signal conductor, and the third ground conductor are spaced at a distance L1 from the first ground conductor;
the first signal conductor, the second signal conductor, and the third ground conductor are spaced at a distance L2 from the second ground conductor;
a spacing between the first signal conductor or the second signal conductor and the third ground conductor is L3; and
L1 <L3 and L2 <L3.

5. The transmission line according to claim 1, further comprising:
a third insulating layer on an opposite side of the second insulating layer from the first insulating layer and having a third relative permittivity higher than the second relative permittivity; wherein
the first ground conductor is opposite to the first signal conductor, the second signal conductor, and the third ground conductor such that the first insulating layer is interposed between the first ground conductor and the first signal conductor, the second signal conductor, and the third ground conductor;
the second ground conductor is opposite to the first signal conductor, the second signal conductor, and the third ground conductor such that the second insulating layer and the third insulating layer are interposed between the second ground conductor and the first signal conductor, the second signal conductor, and the third ground conductor;
the first insulating layer has a thickness D10, the second insulating layer has a thickness D20, the third insulating layer has a thickness D30; and
D20 >D10 and D20 >D30.

6. A method for manufacturing a transmission line, the method comprising:
forming a first ground conductor on a first main surface of a first insulating layer having a first relative permittivity and forming a first signal conductor, a second signal conductor, and a third ground conductor on a second main surface of the first insulating layer, the third ground conductor being between the first signal conductor and the second signal conductor;
forming a second ground conductor on a first main surface of a third insulating layer having a third relative permittivity; and
joining the first insulating layer and the third insulating layer by a second insulating layer having a second relative permittivity lower than the first relative permittivity and the third relative permittivity so that a second main surface of the first insulating layer and a second main surface of the third insulating layer face each other;
wherein, in the joining the first insulating layer and the third insulating layer, the first signal conductor, the second signal conductor, and the third ground conductor are embedded in the second insulating layer such that the first signal conductor, the second signal conductor, and the third ground conductor each include a surface in contact with the second insulating layer and a surface in contact with the first insulating layer, the surface in contact with the second insulating layer being larger than the surface in contact with the first insulating layer.

7. The transmission line according to claim 1, wherein the first and second insulating layers have the same or substantially the same shape in plan view.

8. The transmission line according to claim 5, wherein the first, second, and third insulating layers have the same or substantially the same shape in plan view.

9. The transmission line according to claim 1, wherein each of the first and second insulating layers includes polyimide as a main component.

10. The transmission line according to claim 1, wherein each of the first and second insulating layers includes liquid crystal polymer as a main component.

11. The transmission line according to claim 5, wherein the third insulating layer includes fluoride-component resin as a main component.

12. The transmission line according to claim 2, wherein each of the first and second signal conductors and the third ground conductor have a line shape in the extending direction.

13. The transmission line according to claim 1, wherein the first signal conductor in combination with the first and second ground conductors define a strip line.

14. The transmission line according to claim 1, wherein the second signal conductor in combination with the first and second ground conductors define a strip line.

15. The transmission line according to claim 1, wherein each of opposed ends of the first signal conductor is connected to a terminal electrode by an interlayer connecting conductor.

16. The transmission line according to claim 1, wherein each of opposed ends of the second signal conductor is connected to a terminal electrode by an interlayer connecting conductor.

17. The transmission line according to claim 15, wherein each of the terminal electrodes has a rectangular or substantially rectangular conductor pattern and is physically isolated from the second ground electrode.

18. The transmission line according to claim 15, wherein each of the terminal electrodes has a rectangular or substantially rectangular conductor pattern and is physically isolated from the second ground electrode.
